(19) United States
(12) Patent Application Publication
(10) Pub. No.: US 2025/0215567 A1
(43) Pub. Date: Jul. 3, 2025

(54) SUBSTRATE PROCESSING APPARATUS, NOZZLE, METHOD OF PROCESSING SUBSTRATE, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventor: Yusaku OKAJIMA, Toyama-shi (JP)

(73) Assignee: KOKUSAI ELECTRIC CORPORATION, Tokyo (JP)

(21) Appl. No.: 19/082,746

(22) Filed: Mar. 18, 2025

Related U.S. Application Data
(63) Continuation of application No. PCT/JP2022/035264, filed on Sep. 21, 2022.

(51) Int. Cl. C23C 16/455

(52) U.S. Cl. CPC C23C 16/45561; C23C 16/45574

(57) ABSTRACT

There is provided a technique that includes: a process chamber in which at least one substrate is processed; at least one nozzle including a plurality of gas introduction passages configured to introduce a gas and a fluid communication portion configured to partially bring the plurality of gas introduction passages into fluid communication with each other; and a plurality of gas suppliers configured to supply the gas to the plurality of gas introduction passages.

### CROSS-REFERENCE TO RELATED APPLICATION

This application is a Bypass Continuation Application of PCT International Application No. PCT/JP2022/035264, filed Sep. 21, 2022, the entire contents of which are incorporated herein by reference.

### TECHNICAL FIELD

The present disclosure relates to a substrate processing apparatus, a nozzle, a method of processing a substrate, a method of manufacturing a semiconductor device, and a recording medium.

### BACKGROUND

In the related art, as an example of a substrate processing apparatus used in a process of manufacturing a semiconductor device, a substrate processing apparatus that performs a batch processing of a plurality of substrates is used.

### SUMMARY

Some embodiments of the present disclosure provide a technique capable of uniformly processing a surface of a substrate.

According to some embodiments of the present disclosure, there is provided a technique that includes: a process chamber in which at least one substrate is processed; at least one nozzle including a plurality of gas introduction passages configured to introduce a gas and a fluid communication portion configured to partially bring the plurality of gas introduction passages into fluid communication with each other; and a plurality of gas suppliers configured to supply the gas to the plurality of gas introduction passages.

### BRIEF DESCRIPTION OF DRAWINGS

The accompanying drawings, which are incorporated in and constitute a part of the specification, illustrate embodiments of the present disclosure.

FIG. 1 is a vertical cross-sectional view showing a schematic configuration example of a substrate processing apparatus according to some embodiments of the present disclosure.

FIG. 2 is a horizontal cross-sectional view showing a schematic configuration example of a substrate processing apparatus according to some embodiments of the present disclosure.

FIG. 3 is a vertical cross-sectional view along a gas flow showing a schematic configuration example of a gas supply structure and a nozzle of a substrate processing apparatus according to some embodiments of the present disclosure.

FIG. 4 is a vertical cross-sectional view of a nozzle cut perpendicularly to a gas flow.

FIG. 5 is a perspective view showing a gas guide of a substrate processing apparatus according to some embodiments of the present disclosure.

FIG. 6 is a vertical cross-sectional view showing a substrate support according to some embodiments of the present disclosure.

FIG. 7A is an explanatory diagram for explaining a gas that may be used in some embodiments of the present disclosure.

FIG. 7B is an explanatory diagram for explaining a gas that may be used in some embodiments of the present disclosure.

FIG. 7C is an explanatory diagram for explaining a gas that may be used in some embodiments of the present disclosure.

FIG. 8 is an explanatory diagram for explaining a controller of a substrate processing apparatus according to some embodiments of the present disclosure.

FIG. 9 is a flowchart for explaining a substrate processing flow according to some embodiments of the present disclosure.

FIG. 10 is a perspective view showing a gas guide according to other embodiments of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

Hereinafter, embodiments of the present disclosure will be described with reference to the drawings. Drawings used in the following description are schematic, and dimensional relationships, ratios, and the like of the respective components shown in the drawings may not match actual ones. Further, dimensional relationships, ratios, and the like of the respective components among plural drawings may not match one another. Further, in the drawings, a direction of an arrow U indicates a vertical upward direction, and a direction of an arrow D indicates a vertical downward direction.

### (1) Configuration of Substrate Processing Apparatus

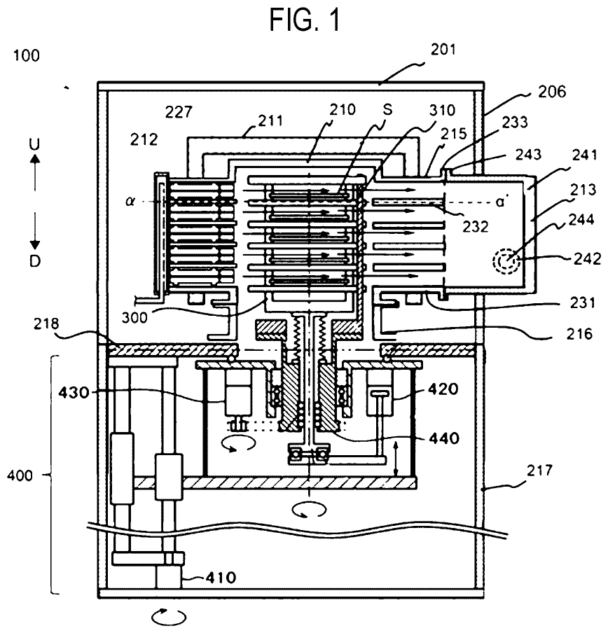

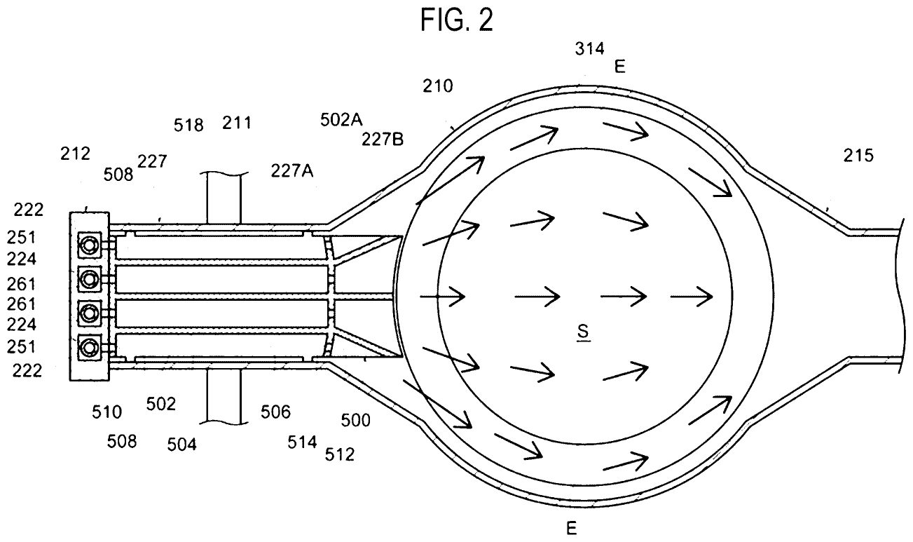

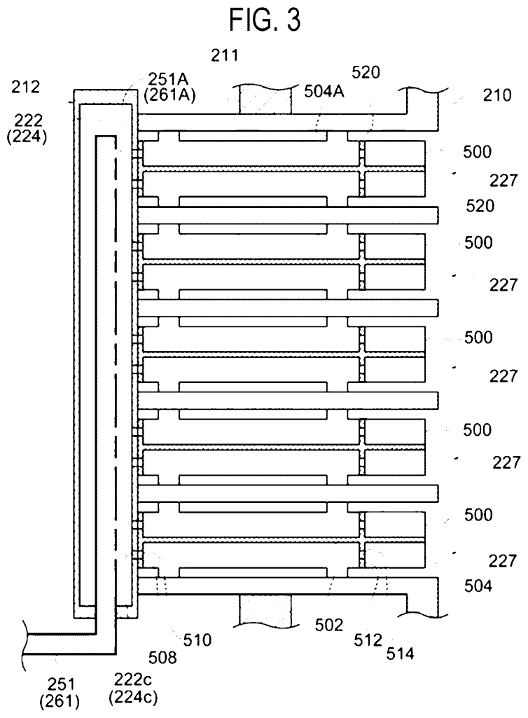

A schematic configuration of a substrate processing apparatus 100 according to some embodiments of the present disclosure will be described with reference to FIGS. 1 to 9. FIG. 1 is a side cross-sectional view of the substrate processing apparatus 100, and FIG. 2 is a cross-sectional view taken along line α-α′ in FIG. 1. FIG. 3 is an explanatory diagram for explaining a relationship among a gas supply structure 212, a nozzle 227, a reaction tube 210, and a heater 211.

Next, specific contents will be described. As shown in FIG. 1, the substrate processing apparatus 100 includes a housing 201, which includes a reaction tube storage chamber 206 and a delivery chamber 217. The reaction tube storage chamber 206 is arranged over the delivery chamber 217.

The reaction tube storage chamber 206 includes a cylindrical reaction tube 210 extending in a vertical direction, a heater 211 as a heating part (e.g., a furnace body) installed at an outer periphery of the reaction tube 210, a gas supply structure 212 and a nozzle 227 configured to supply a gas, and a gas exhaust structure 213 configured to exhaust the gas. Herein, the reaction tube 210 is also called a process chamber, and a space inside the reaction tube 210 is also called a process space. The reaction tube 210 is configured to be capable of storing a substrate support 300, which is described below.

The heater 211 is provided with resistance heaters on an inner surface thereof facing the reaction tube 210, and a heat insulator is installed to surround the resistance heaters. Therefore, the heater 211 is configured to be less affected by heat on an outside of the heater 211, i.e., a side not facing the reaction tube 210. A heater controller (not shown) is electrically connected to the resistance heaters of the heater 211. The heater controller may control an on/off operation and a heating temperature of the heater 211. The heater 211 may heat a gas, which is described below, to a temperature at which the gas may be thermally decomposed. The heater 211 is also called a process chamber heater or a first heater.

As shown in FIGS. 1 to 3, the gas supply structure 212 and the nozzle 227 are installed at an upstream side of the reaction tube 210 in a gas flow direction, and a gas is horizontally supplied to the reaction tube 210 from the gas supply structure 212 and the nozzle 227. The gas exhaust structure 213 is installed at a downstream side of the reaction tube 210 in the gas flow direction, and the gas within the reaction tube 210 is exhausted via the gas exhaust structure 213. The gas supply structure 212 and the nozzle 227 are detachably fixed.

A downstream gas guide 215 configured to regulate a flow of the gas exhausted from the reaction tube 210 is installed between the reaction tube 210 and the gas exhaust structure 213. A lower end of the reaction tube 210 is supported by a manifold 216.

The reaction tube 210, the nozzle 227, and the downstream gas guide 215 are structurally continuous and are made of a material such as quartz, SiC or the like. These are constituted by a heat transmitter configured to transmit heat radiated from the heater 211. The heat from the heater 211 heats a substrate S used in the semiconductor device or the gas.

The gas supply structure 212 is installed at a back side of the nozzle 227 when viewed from the reaction tube 210. As shown in FIG. 2, the gas supply structure 212 includes a distributor 222 configured to be capable of being in fluid communication with a gas supply pipe 251 to be described below, and a distributor 224 configured to be capable of being in fluid communication with a gas supply pipe 261, which is described below. Each of the distributor 222 and the distributor 224 is a passage extending in the vertical direction. Since each of the distributor 222 and the distributor 224 is configured to be capable of distributing the gas to the respective nozzles 227, it is also called a gas distributor.

As shown in FIG. 2, the gas supply structure 212 is provided with distributors 222 on both sides in a width direction thereof, and is provided with two distributors 224 on a central side in the width direction.

As shown in FIGS. 2 and 3, a downstream portion of the gas supply pipe 251 as an example of a gas supplier is inserted into the distributor 222, and a downstream portion of the gas supply pipe 261 as an example of a gas supplier is inserted into the distributor 224. A plurality of holes 251A configured to inject the gas are formed at intervals in the vertical direction at a side portion of the gas supply pipe 251, and a plurality of holes 261A configured to inject the gas are formed at intervals in the vertical direction at a side portion of the gas supply pipe 261. The holes 251A and 261A may be referred to as openings.

As shown in FIGS. 2 to 4, at the downstream side of the gas supply structure 212, a plurality of cylindrical nozzles 227 are stacked in the vertical direction, which is the same direction as a stacking direction of substrates S, which is described below. The nozzles 227 are installed in multiple stages in a height direction of a substrate holder, which is described below. Further, the plurality of nozzles 227 may also be referred to as one nozzle 227 whose interior is divided into a plurality of flow paths in the vertical direction.

Different types of gases are supplied to the gas supply pipes 251 and 261 as described below.

As shown in FIGS. 2 and 3, at a side surface of the gas supply structure 212 near the nozzle 227, vent holes 222c configured to be in fluid communication with the distributor 222 are formed at intervals in the vertical direction, and vent holes 224c configured to be in fluid communication with the distributor 224 are formed at intervals in the vertical direction.

### Structure of Nozzle

As shown in FIG. 2, the nozzle 227 includes a straight portion 227A extending linearly from the gas supply structure 212 toward the reaction tube 210, and an enlarged-diameter portion 227B installed at a side of the straight portion 227A near the reaction tube 210 and gradually expanding toward the reaction tube 210. The nozzle 227 may be referred to as a gas injector configured to inject a gas.

As shown in FIGS. 2, 3, and 5, a gas guide 500 is accommodated inside the nozzle 227. The gas guide 500 is constituted by one horizontal plate 502 and a plurality of vertical plates 504 (in the embodiments, six vertical plates including three vertical plates erected on an upper surface of the horizontal plate 502 and three vertical plates erected on a lower surface of the horizontal plate 502). Eight gas introduction portions 506 are formed inside the nozzle 227. The gas introduction portions (or gas introduction passages) 506 are passages through which a gas passes. A portion of the nozzle 227 where the gas guide 500 is arranged may be called a gas guide part. In addition, since the gas guide 500 is constituted by the horizontal plate 502 and the vertical plates 504, a passage resistance of the gas flowing through the nozzle 227 is reduced.

As shown in FIG. 2, the vertical plates 504 are arranged to extend linearly in the straight portion 227A of the nozzle 227. Further, the vertical plates 504 are arranged in the enlarged-diameter portion 227B of the nozzle 227 such that a vertical plate 504 on a central side thereof extends linearly in the same direction as the vertical plates 504 arranged in the straight portion 227A, and the vertical plates 504 on both sides in a nozzle width direction are installed near the reaction tube 210 and inclined to widen a distance from the vertical plate 504. The inclined vertical plates 504 on both sides are inclined toward edges E in a width direction of the substrate S accommodated in the reaction tube 210 (the same direction as the width direction of the nozzle 227). In other words, the vertical plates 504 on both sides are widened outward in the width direction from an upstream side to a downstream side of the flow of the processing gas.

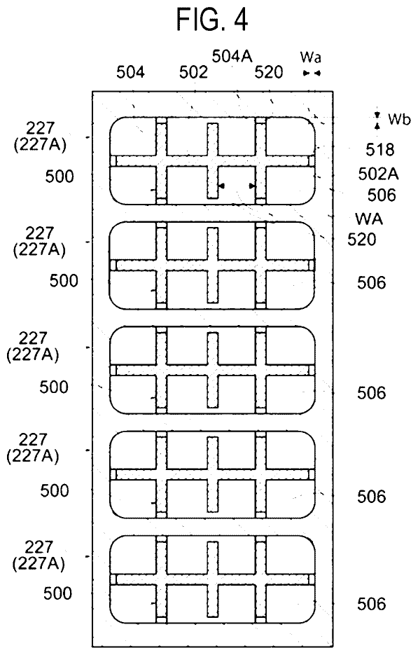

As shown in FIG. 4, in the embodiments of the present disclosure, cross-sectional areas (areas when viewed in a cross section perpendicular to the gas flow) of the respective gas introduction portions 506 arranged in the straight portion 227A of the nozzle 227 are approximately the same.

As shown in FIGS. 2, 3 and 5, the gas guide 500 includes a wall 508 at an end thereof near the gas supply structure 212. The wall 508 includes holes 510 formed so as to be in fluid communication with the vent holes 222c and 224c of the gas supply structure 212.

Further, the gas guide 500 includes walls 512 at boundaries between the straight portions and the inclined portions of the vertical plates 504. Each of the walls 512 includes a hole 514 formed so as to allow a gas to pass therethrough.

Two protrusions 502A are formed at a distance from each other on both side ends in the width direction of the horizontal plate 502. The protrusions 502A come into contact with an inner wall surface of the nozzle 227, such that a fluid communication portion 518 with a width Wa is formed between the side end of the horizontal plate 502 and the inner wall surface of the nozzle 227, as shown in FIG. 4. The fluid communication portion 518 may be installed partially between the side end of the horizontal plate 502 and the inner wall surface of the nozzle 227. The number of protrusions 502A installed at the side end of the horizontal plate 502 may be one, or three or more.

Two protrusions 504A are formed at a distance from each other on both side ends in the width direction of the vertical plate 504. The protrusions 504A come into contact with the inner wall surface of the nozzle 227, such that a fluid communication portion 520 with a width Wb is formed between the side end of the vertical plate 504 and the inner wall surface of the nozzle 227, as shown in FIG. 4. The fluid communication portion 520 may be installed partially between the side end of the vertical plate 504 and the inner wall surface of the nozzle 227. The number of protrusions 504A installed at the side end of the vertical plate 504 may be one, or three or more.

By accommodating the gas guide 500 inside the nozzle 227 in this manner, the four gas introduction portions 506 arranged side by side in a horizontal direction may allow a portion of the gas passing through one gas introduction portion 506 to enter the other gas introduction portion 506, which is adjacent to the one gas introduction portion 506 in the horizontal direction, from the one gas introduction portion 506 via the fluid communication portion 520. Further, the four gas introduction portions 506 may allow a portion of the gas passing through the other gas introduction portion 506 to enter the one gas introduction portion 506 from the other gas introduction portion 506 via the fluid communication portion 520.

Further, in two gas introduction portions 506 adjacent to each other in the vertical direction on both sides in the nozzle width direction, a portion of the gas passing through the gas introduction portion 506 on an upper side thereof may be allowed to enter the gas introduction portion 506 on a lower side thereof from the gas introduction portion 506 on the upper side via the fluid communication portion 518 of the horizontal plate 502. Further, a portion of the gas passing through the gas introduction portion 506 on the lower side may be allowed to enter the gas introduction portion 506 on the upper side from the gas introduction portion 506 on the lower side via the fluid communication portion 518.

As an example, when supplying the gas to the gas introduction portions 506 on both sides in the width direction of the nozzle 227, the gas may be injected from the gas introduction portions 506 on both sides in the width direction toward the substrate S, and the gas may also be injected from the two gas introduction portions 506 on the inner side in the width direction toward the substrate S. To create a wide flow which is symmetrical in a left-right direction, the gas introduction portions 506 are partially in fluid communication with each other by the fluid communication portion 520, and the vertical plates 504 on both sides are expanded outward in the width direction from the upstream side to the downstream side of the flow of the processing gas. Therefore, the gas may be allowed to flow as the wide flow which is symmetrical in the left-right direction with the substrate S as a center. Further, arrows in FIG. 2 indicate the flow of the gas. Therefore, the gas supplied from the gas supply structure 212 to the nozzle 227 may be regulated by the gas guide 500 and supplied to the surface of the substrate S. Further, the fluid communication portions (or fluid communication slits) 518 and 520 may be called gaps or slits.

### Downstream Gas Guide

As shown in FIG. 1, the downstream gas guide 215 is configured such that, in a state where the substrate S is supported by the substrate support 300, a ceiling of the downstream gas guide 215 is higher than a position of an uppermost substrate S and a bottom of the downstream gas guide 215 is lower than a position of a lowermost substrate S on the substrate support 300.

The downstream gas guide 215 includes a housing 231 and partition plates 232. Portions of the partition plates 232 facing the substrate S extend in the horizontal direction so as to be larger than at least a diameter of the substrate S. The horizontal direction mentioned herein refers to a side wall direction of the housing 231. Furthermore, the partition plates 232 are arranged in the vertical direction. The partition plates 232 are fixed to the side wall of the housing 231 and configured so as not to allow the gas to move beyond the partition plates 232 to an adjacent upper or lower area. By preventing the gas from moving beyond the partition plates 232, it is possible to reliably form a gas flow, which is described below. A flange 233 is installed at a side of the housing 231 which comes in contact with the gas exhaust structure 213.

The partition plate 232 is formed in a continuous structure without holes. A central position between the partition plates 232 is provided at a position corresponding to the substrate S and corresponding to a central position of the nozzle 227 in the vertical direction. According to such a structure, the gas supplied from each nozzle 227 forms a flow passing over the substrate S and the partition plate 232 as indicated by the arrows in the drawing. In this case, the partition plate 232 extends in the horizontal direction and is formed in a continuous structure without holes.

According to such a structure, a pressure loss of the gas exhausted from each substrate S may be made uniform. Therefore, the gas flow of the gas passing through each substrate S is formed in the horizontal direction toward the gas exhaust structure 213 while the flow in the vertical direction is suppressed.

By installing the partition plate 232 corresponding to the nozzle 227, a pressure loss in the vertical direction may be made uniform at each of upstream and downstream sides of each substrate S. Therefore, a horizontal gas flow may be reliably formed throughout the nozzle 227, the substrate S, and the partition plate 232 with the flow in the vertical direction suppressed.

The gas exhaust structure 213 is installed at a downstream side of the downstream gas guide 215. The gas exhaust structure 213 is mainly constituted by a housing 241 and a gas exhaust pipe connector 242. A flange 243 is installed at the housing 241 near the downstream gas guide 215.

The gas exhaust structure 213 is in fluid communication with a space of the downstream gas guide 215. The housings 231 and 241 are configured such that heights of the housings 231 and 241 are continuous. The housings 231 and 241 are configured such that a height of a ceiling of the housing 231 is equivalent to a height of a ceiling of the housing 241, and a height of a bottom of the housing 231 is equivalent to a height of a bottom of the housing 241.

The gas that passed through the downstream gas guide 215 is exhausted via an exhaust hole 244. At this time, since the gas exhaust structure does not include a configuration such as a partition plate, a gas flow including a vertical flow is formed toward an exhaust hole 244.

The delivery chamber 217 is installed under the reaction tube 210 via the manifold 216. In the delivery chamber 217, the substrate S is horizontally mounted (e.g., placed) on the substrate support (hereinafter, sometimes simply referred to as a boat) 300 by a vacuum transfer robot (not shown), or the substrate S is discharged from the substrate support 300 by the vacuum transfer robot.

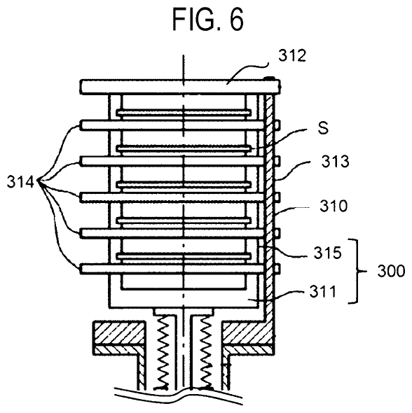

As shown in FIG. 1, an inside of the delivery chamber 217 may accommodate the substrate support 300 shown in FIG. 6, a partition plate support 310, and a vertical driver 400 constituting a first driver configured to drive the substrate support 300 and partition plate support 310 (collectively referred to as a substrate holder) in vertical and rotational directions. FIG. 1 shows a state in which the substrate holder is raised by the vertical driver 400 and accommodated in the reaction tube.

Next, the substrate support which is a component configured to support the substrate S will be described in detail with reference to FIGS. 1 and 6. The substrate support is constituted by at least the substrate support 300. The substrate support transfers the substrate S by a vacuum transfer robot through a substrate entrance (not shown) inside the delivery chamber 217, or transfers the transferred substrate S into the reaction tube 210 to perform a process of forming a thin film on the surface of the substrate S. The substrate support may also include the partition plate support 310.

The partition plate support 310 includes a plurality of disk-shaped partition plates 314 fixed at predetermined pitches to pillars 313 supported between a base 311 and a top plate 312. The substrate support 300 is configured such that a plurality of support rods 315 are supported by the base 311, and a plurality of substrates S are supported at predetermined intervals by the plurality of support rods 315.

As shown in FIG. 6, a plurality of substrates S are horizontally mounted at predetermined intervals on the substrate support 300 by the plurality of support rods 315 supported on the base 311. The substrates S supported by the support rods 315 are separated by the disk-shaped partition plates 314 fixed (for example, supported) at predetermined intervals on the pillars 313 supported by the partition plate support 310. In this regard, the partition plates 314 are arranged above or below the substrate S, or above and below the substrate S.

The predetermined interval between the substrates S horizontally mounted on the substrate support 300 is the same as a vertical interval between the partition plates 314 fixed to the partition plate support 310. In addition, a diameter of the partition plate 314 is set to be larger than a diameter of the substrate S.

The substrate support 300 supports a plurality of substrates S, for example, five substrates S, in multiple stages in the vertical direction by using the plurality of support rods 315. The base 311 and the plurality of support rods 315 are made of a material such as quartz or SiC. Herein, although an example in which five substrates S are supported by the substrate support 300 is shown, the present disclosure is not limited thereto. For example, the substrate support 300 may be configured to be capable of supporting approximately 5 to 50 substrates S (5 or more and 50 or less).

As shown in FIG. 1, the partition plate support 310 and the substrate support 300 are driven by a vertical driver 400 in the vertical direction between the reaction tube 210 and the delivery chamber 217 and in the rotational direction around a center of the substrate S supported by the substrate support 300.

The vertical driver 400 constituting a first driver includes, as drive sources, a vertical drive motor 410, a rotational drive motor 430, and a boat lift 420 including a linear actuator as a substrate support elevator configured to drive the substrate support 300 in the vertical direction.

### Gas Supply System

As shown in FIGS. 2 and 3, in the embodiments of the present disclosure, various gases may be supplied to the distributors 222 on both sides in the width direction via the gas supply pipes 251, and various gases may also be supplied to the distributors 224 on the central side via the gas supply pipe 261. A gas source, a mass flow controller (MFC) as a flow rate controller (flow rate control part), and a valve as an opening/closing valve (not shown), which are known configurations in the substrate processing apparatus, are connected to an upstream side of the gas supply pipe 251.

As an example, a first gas source configured to supply a first gas containing a first element (also referred to as a “first-element-containing gas”), a second gas source configured to supply a second gas containing a second element (also referred to as a “second-element-containing gas”), and an inert gas source configured to supply an inert gas are connected to the gas supply pipe 251. An inert gas, for example, a nitrogen (N₂) gas is supplied from the inert gas source. The inert gas may be a gas other than the nitrogen (N₂) gas.

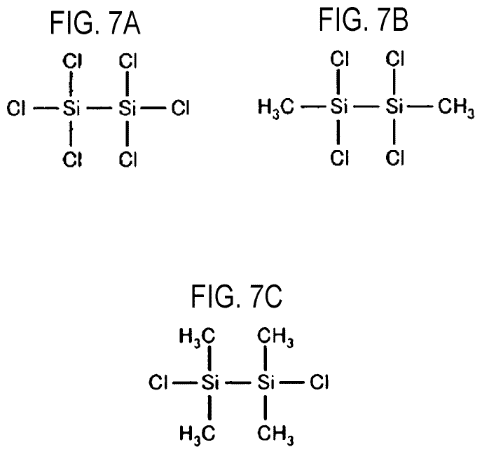

The first gas is a precursor gas, i.e., a processing gas. Herein, as an example, the first gas is a gas in which at least two silicon atoms (Si) are bonded, for example, a gas containing Si and chlorine (Cl), and is a precursor gas containing Si—Si bonds such as a hexachlorodisilane (Si₂Cl₆, abbreviated as HCDS) gas shown in FIG. 7A. However, the first gas may be another gas. As shown in FIG. 7A, the HCDS gas contains Si and a chloro group (chloride) in its chemical structural formula (in one molecule).

Energy of the Si—Si bond is at such a level that the Si—Si bond is decomposed by colliding with a wall constituting a recess (not shown) such as a groove or the like of the substrate S, which is described below, in the reaction tube 210. Herein, the decomposition means that the Si—Si bond is cut. That is, the Si—Si bond is cut by colliding with the wall.

The second-element-containing gas is a processing gases, and may be considered as a reaction gas or a modifying gas.

Herein, the second-element-containing gas contains a second element different from the first element. The second element is, for example, any one of oxygen (O), nitrogen (N), and carbon (C). In the embodiments, the second-element-containing gas is, for example, a nitrogen-containing gas. Specifically, the second-element-containing gas is a hydrogen nitride-based gas containing a N—H bond, such as an ammonia (NH₃) gas, a diazene (N₂H₂) gas, a hydrazine (N₂H₄) gas, or a N₃H₈ gas. However, the second-element-containing gas may be another gas.

In the substrate processing process, the inert gas supplied from the inert gas source is used as a purge gas that purges the gas remaining in various pipes, the nozzle 227, and the reaction tube 210.

### Exhaust System

Next, an exhaust system will be described. As shown in FIG. 1, an exhaust system (not shown) configured to exhaust an atmosphere in the reaction tube 210 is connected to the gas exhaust pipe connector 242.

The exhaust system is connected to a vacuum pump as a vacuum exhauster via a valve as an opening/closing valve and an auto pressure controller (APC) valve as a pressure regulator (e.g., a pressure regulation part), and is configured to be capable of vacuum-exhausting an inside of the reaction tube 210 such that an internal pressure of the reaction tube 210 reaches a predetermined pressure (e.g., degree of vacuum). The exhaust system is also called a process chamber exhaust system.

### Controller

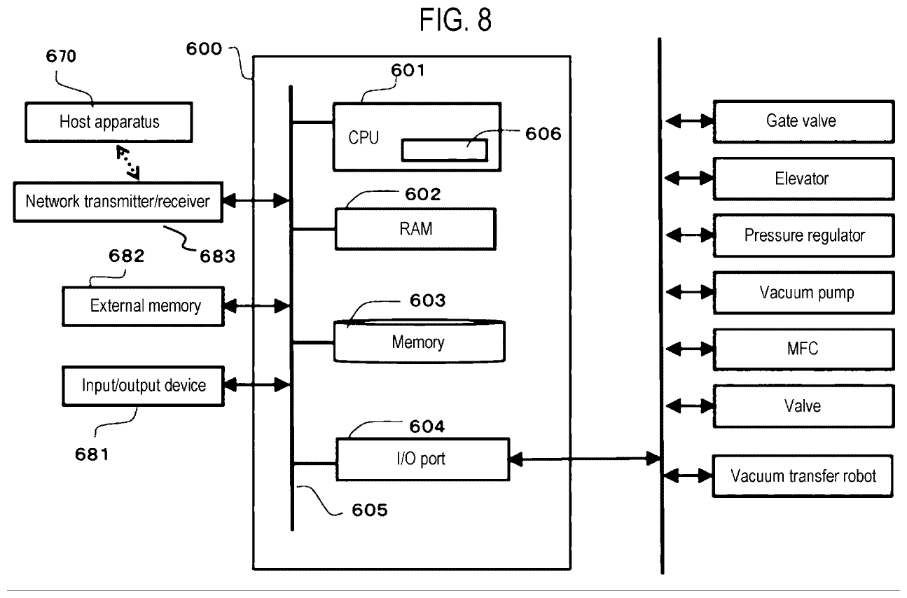

The substrate processing apparatus 100 includes a controller 600 shown in FIG. 8 configured to control an operation of each component of the substrate processing apparatus 100.

The controller 600, which is a control part (control means or unit), is constituted as a computer including a central processing unit (CPU) 601, a random access memory (RAM) 602, a memory 603, and an I/O port 604. The RAM 602, the memory 603, and the I/O port 604 are configured to be capable of exchanging data with the CPU 601 via an internal bus 605. Transmission and reception of data within the substrate processing apparatus 100 is performed according to instructions from a transmission/reception instructor 606, which is also a function of the CPU 601.

The controller 600 is provided with a network transmitter/receiver 683 that is connected to a host apparatus 670 via a network. The network transmitter/receiver 683 is configured to be capable of receiving information, such as information on a processing history and a processing schedule of the substrate S stored in a pod (not shown), from the host apparatus 670.

The memory 603 includes, for example, a flash memory, a hard disk drive (HDD), or the like. A control program that controls an operation of the substrate processing apparatus, a process recipe in which procedures and conditions of substrate processing are written, and the like are readably stored in the memory 603.

The process recipe functions as program that is combined to cause the controller 600 to execute respective procedures in a substrate processing process, which is described below, to obtain a predetermined result. Hereinafter, the process recipe and the control program are collectively and simply referred to as a program. When the term “program” is used in the present disclosure, it may include a process recipe, a control program, or both. The RAM 602 is constituted as a memory area (e.g., a work area) in which program and data read by the CPU 601 are temporarily stored.

The I/O port 604 is connected to each component of the substrate processing apparatus 100. The CPU 601 is configured to read a control program from the memory 603 and execute the read control program, and to read a process recipe from the memory 603 in response to an input of an operation command from an input/output device 681, or the like. The CPU 601 is configured to be capable of controlling the substrate processing apparatus 100 in accordance with contents of the read process recipe.

The CPU 601 includes a transmission/reception instructor 606. The controller 600 according to the embodiments of the present disclosure may be configured by installing the program in the computer by using an external memory (e.g., a magnetic disc such as a hard disk or the like, an optical disc such as a DVD or the like, a magneto-optical disc such as a MO or the like, or a semiconductor memory such as a USB memory or the like) 682 storing the above-mentioned program. An apparatus (means or unit) configured to supply the program to the computer is not limited to supplying the program via the external memory 682. For example, the program may be provided by using a communication apparatus (e.g., a communication means or unit) such as the Internet or a dedicated line, instead of using the external memory 682. The memory 603 and the external memory 682 are constituted as computer-readable recording media. Hereinafter, these are generally and simply referred to as a recording medium. Further, in the present disclosure, when the term “recording medium” is used, it may include the memory 603, the external memory 682, or both.

### Processing Process

Next, as a semiconductor manufacturing process, a process of forming a thin film on a substrate S by using the substrate processing apparatus 100 with the above-described configuration will be described. In the following description, the operation of each component constituting the substrate processing apparatus is controlled by the controller 600.

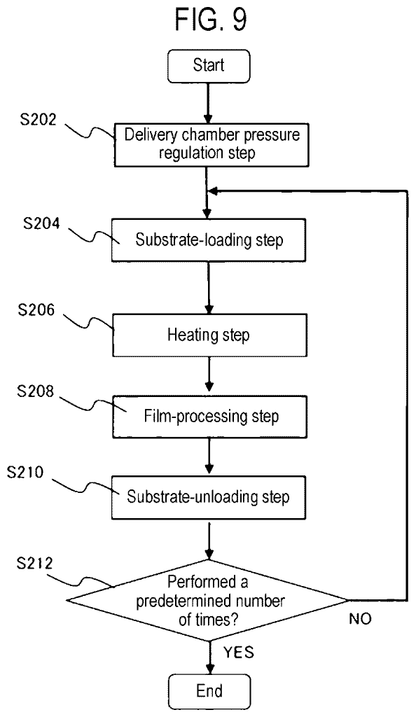

Herein, a film formation process in which a first gas and a second gas are used and supplied alternately to form a film on a substrate S will be described with reference to FIG. 9.

### S202

First, a delivery chamber pressure regulation step S202 will be described. Herein, an internal pressure of the delivery chamber 217 is set to a vacuum level pressure. Specifically, an exhaust system (not shown) connected to the delivery chamber 217 is operated, and an atmosphere in the delivery chamber 217 is exhausted such that the atmosphere in the delivery chamber 217 is at a vacuum level.

The heater 211 may be operated in parallel with this step. When the heater 211 is operated, it is operated at least during a film-processing step S208, which is described below.

### S204

Next, a substrate-loading step S204 will be described (an example of a process of loading a substrate according to the present disclosure). The delivery chamber 217 is set to a vacuum level, and the substrate S is loaded into the delivery chamber 217 from an adjacent vacuum transfer chamber (not shown).

At this time, the substrate support 300 is on standby in the delivery chamber 217, and the substrate S are delivered to the substrate support 300. When a predetermined number of substrates S are delivered to the substrate support 300, the vacuum transfer robot is retreated, and the substrate support 300 is raised to move the substrates S into the reaction tube 210.

When the substrates S are moved into the reaction tube 210, the substrates S are positioned such that they are aligned with a height of the nozzle 227.

### S206

A heating step S206 will be described. Once the substrates S are loaded into the reaction tube 210, the heater 211 is controlled such that surface temperatures of the substrates S reach a predetermined temperature. As an example, the temperature is in a high temperature range which is described below. For example, the substrate is heated to 400 degrees C. or higher and 800 degrees C. or lower. The temperature may be 500 degrees C. or higher and 700 degrees C. or lower, but is not limited thereto.

### S208

A film-processing step S208 will be described. After the heating step S206, the film-processing step S208 is performed. In the film-processing step S208, a first gas is supplied into the reaction tube 210 according to the process recipe, and the exhaust system 280 is controlled to exhaust the processing gas from the inside of the reaction tube 210, thereby performing the film-processing step. This film-processing step S208 corresponds to a step of supplying a processing gas to the substrate S according to the present disclosure. At this time, the first gas and the second gas may be alternately supplied into the reaction tube 210 to perform an alternate supply process, or the second gas may be present in the processing space simultaneously with the first gas to perform a CVD process. The supply and exhaust of the gas are controlled such that the internal pressure of the reaction tube 210 reaches a predetermined pressure.

The following method may be considered as an alternate supply process, which is a specific example of a method of processing a film. For example, an alternate supply process, in which the first gas is supplied into the reaction tube 210 in a first step, the second gas is supplied into the reaction tube 210 in a second step, the inert gas is supplied into the reaction tube 210 between the first step and the second step as a purge step while the atmosphere in the reaction tube 210 is exhausted, and a combination of the first step, the purge step, and the second step is performed multiple times, is performed to form a desired film.

The supplied gas forms an optimal gas flow for processing the substrates S by the nozzle 227, spaces above the substrates S, and the downstream gas guide 215. For example, when supplying the first gas into the reaction tube 210, the first gas is supplied to at least two gas introduction portions 506. Herein, the first gas is supplied from the distributors 222 on both sides toward the nozzle 227. The first gas supplied from the distributors 222 passes through the gas introduction portions 506 on both sides of the nozzle toward the reaction tube 210, and a portion of the first gas flows through the fluid communication portion 520 of the vertical plate 504 to the adjacent gas introduction portions 506 on the central side of the nozzle. As a result, finally, the same amount of the first gas may be discharged at the same velocity along the surfaces of the substrates S from downstream ends of the gas introduction portions 506 on both sides and downstream ends of the gas introduction portions 506 on the central side. Further, the nozzle 227 includes the fluid communication portion 520, and the vertical plates 504 on both sides are widened outward in the width direction from the upstream side to the downstream side of the flow of the processing gas, such that the first gas is supplied to the surfaces of the substrates S so as to form the wide flow which is symmetrical in the left-right direction with respect to the substrates S. Further, the first gas is injected horizontally from the nozzle 227 and supplied in parallel along the surfaces of the horizontally arranged substrates S, thereby uniformly processing the surfaces of the substrates S.

As shown in FIG. 2, the inclined vertical plates 504 on both sides are inclined toward the edges E in the width direction (the same direction as the width direction of the nozzle 227) of the substrate S accommodated in the reaction tube 210. Therefore, the flow of the first gas supplied to the surface of the substrate S is guided by the gas guide 500 so as to become the wide flow which is symmetrical in the left-right direction. Therefore, the entire surface of the substrate S may be uniformly processed by using the first gas. Further, as shown in FIG. 1, the nozzles 227 are installed in multiple stages in the height direction of the substrate holder. The nozzle 227 is installed for each substrate S, such that each substrate S may be processed uniformly.

As shown in FIG. 4, in the nozzle 227, an amount of gas entering the gas introduction portions 506 on the central side in the nozzle width direction from the gas introduction portions 506 on both sides in the nozzle width direction is optimized by setting the width Wb of the fluid communication portion 520 to 5 to 10 (5 or more and 10 or less) % of a width WA of the gas introduction portion 506. In a case where the width Wb of the fluid communication portion 520 is 5% or less of the width WA of the gas introduction portion, a directionality of the gas becomes stronger, and the gas flow may become strong in a direction of the vertical plate 504 installed near the reaction tube 210 and inclined to widen the distance from the vertical plate 504 on the central side. In a case where the width Wb of the fluid communication portion 520 is 10% or more of the width WA of the gas introduction portion, the directionality of gas becomes weaker, and a gas flow toward a central side of a wafer 200 becomes stronger. Thus, an amount and a velocity of the first gas discharged from each gas introduction portion 506 toward the substrate S may be made to be uniform, and an average flow velocity of the gas discharged from each gas introduction portion 506 may be increased. When the second gas is supplied into the reaction tube 210, the gas flow may be guided by the gas guide 500 in the same manner as when the first gas is supplied into the reaction tube 210, thereby uniformly processing the entire surface of the substrate S.

Further, in a case where the velocity of the gas discharged from each gas introduction portion is different for each gas introduction portion, in other words, in a case where there is a gas introduction portion where the velocity of the gas is excessively high, a vortex may be generated at a downstream side of the pertinent gas introduction portion, and multiple adsorption may occur at a specific portion of the substrate S, which may cause singularities. Further, in a case where the velocity of the gas becomes excessive, when processing a substrate S with a groove (e.g., a recess not shown) formed on the surface thereof, it may be difficult for the gas to reach a bottom of the groove, which may cause a processing defect at the bottom of the groove. However, in the nozzle 227 of the embodiments of the present disclosure, an amount and a flow velocity of the gas discharged from each gas introduction portion 506 toward the substrate S may be made to be uniform, which makes it possible to suppress an occurrence of singularities or an occurrence of processing defect at the bottom of the groove. As described above, according to the present disclosure, one or more effects may be obtained.

### S210

A substrate-unloading step S210 will be described. In S210, the processed substrates S are unloaded from the delivery chamber 217 in the reverse order to the substrate-loading step S204 described above.

### S212

A determination step S212 will be described. In this step, it is determined whether or not a substrate was processed a predetermined number of times. If it is determined that the substrate was not processed the predetermined number of times, the process returns to the substrate-loading step S204, and the next substrate S is processed. If it is determined that the substrate was processed the predetermined number of times, the process ends.

In the above description, expressions such as “approximately the same,” “the same,” “equivalent”, and the like are used. It goes without saying that these expressions may include “substantially the same.”

### First Method of Other Gas Supply Methods

In the nozzle 227 of the embodiments, the first gas or the second gas may be diluted with an inert gas (e.g., nitrogen gas (N₂)) and supplied to the substrate S. For example, an inert gas is supplied to the gas introduction portion 506 other than the at least two gas introduction portions 506 that supply the processing gases. When diluting the first gas with the inert gas, the first gas is supplied from the distributors 222 to the gas introduction portions 506 on both sides of the nozzle, and the inert gas is supplied from the distributors 224 to the gas introduction portions 506 on the central side of the nozzle.

As a result, a portion of the first gas flowing through the gas introduction portions 506 on both sides of the nozzle enters the adjacent gas introduction portions 506 on the central side of the nozzle via the fluid communication portions 520 of the vertical plate 504, and a portion of the inert gas flowing through the gas introduction portions 506 on the central side of the nozzle enters the adjacent gas introduction portions 506 on both sides of the nozzle via the fluid communication portions 520. As a result, in each gas introduction portion 506, the first gas and the inert gas are uniformly mixed in the gas introduction portion 506 before reaching the downstream end of each gas introduction portion 506, and the first gas uniformly diluted with the inert gas may be supplied from each gas introduction portion 506 toward the substrate S.

A flow rate of the inert gas may be set to, for example, 10% or less of a flow rate of the processing gas so as not to dilute the processing gas excessively.

### Second Method of Other Gas Supply Methods

Further, in the nozzle 227 of the embodiments, multiple different types of gases, for example, a first gas and a second gas, may be mixed inside the nozzle 227, and a mixed gas of the first gas and the second gas may be discharged toward the substrate S.

In this case, the first gas and the second gases are supplied to at least two gas introduction portions 506. For example, the first gas is supplied to one of the gas introduction portions 506 on the central side of the nozzle, and the second gas is supplied to the other adjacent gas introduction portion. As a result, the first gas and the second gas come and go between the one gas introduction portion 506 and the other gas introduction portion 506 on the central side of the nozzle via the fluid communication portions 520 of the vertical plate 504. Thus, the first gas and the second gas are mixed uniformly before reaching the downstream end of the gas introduction portion 506. Further, the mixed gas may be caused to enter the gas introduction portions 506 on both sides in the width direction of the nozzle and may be discharged from each gas introduction portion 506 toward the substrate S before reaching the downstream end. As a result, the entire surface of the substrate S may be uniformly processed with the mixed gas. Further, an inert gas may be supplied to the gas introduction portions 506 (in this case, the gas introduction portions 506 on both sides of the nozzle) other than the two adjacent gas introduction portions 506 that supply different types of gases, thereby diluting the mixed gas. In this case, a flow rate of the inert gas may be 50% or less of a flow rate of the mixed gas obtained by mixing two kinds of processing gases (suppression of excessive dilution). In a case where the flow rate of the inert gas is 50% or more of the flow rate of the mixed gas obtained by mixing two kinds of processing gases, the mixed gas will be diluted excessively. In addition, in the case where the flow rate of the inert gas is 50% or more of the flow rate of the mixed gas obtained by mixing two kinds of processing gases, the diluted mixed gas will flow in a larger amount from the gas introduction portions 506 on both sides of the nozzle to which the inert gas is supplied than the gas introduction portions 506 on the central side of the nozzle.

In the substrate processing apparatus 100 of the embodiments of the present disclosure, different types of gases are mixed inside the nozzle 227, such that the different types of gases are not mixed in each distributor. Therefore, it is possible to suppress generation of particles which may otherwise generated when the gases are mixed in each distributor.

### Other Embodiments

Although the embodiments of the present disclosure are specifically described above, the present disclosure is not limited thereto, and various modifications may be made without departing from the spirit of the present disclosure.

For example, in the above-described embodiments, the case where the film is formed on the substrate S by using the first gas and the second gas in the film formation process performed by the substrate processing apparatus 100 is described by way of example. However, the present disclosure is not limited thereto. That is, other types of thin films may be formed by using other types of gases as the processing gases used in the film formation process. Furthermore, even in a case where three or more types of processing gases are used, the present disclosure may be applied as long as the processing gases are alternately supplied to perform the film formation process. Specifically, the first element may be, for example, various elements such as titanium (Ti), silicon (Si), zirconium (Zr), hafnium (Hf), and the like. In addition, the second element may be, for example, nitrogen (N), oxygen (O), and the like. Further, the first element may be Si as described above.

In the above-described embodiments, the HCDS gas is used as an example of the first gas. However, the first gas is not limited thereto as long as the first gas contains silicon and a Si—Si bond. For example, a tetrachlorodimethyldisilane ((CH₃)₂Si₂Cl₄, abbreviated as TCDMDS) gas or a dichlorotetramethyldisilane ((CH₃)₄Si₂Cl₂, abbreviated as DCTMDS) may be used. As shown in FIG. 7B, TCDMDS contains a Si—Si bond and further contains a chloro group and an alkylene group. Further, as shown in FIG. 7C, DCTMDS contains a Si—Si bond and further contains a chloro group and an alkylene group.

For example, in each of the above-described embodiments, the film formation process is exemplified as the process performed by the substrate processing apparatus. However, the present disclosure is not limited thereto. That is, the present disclosure may be also applied to a film formation process of a film other than the thin film exemplified in each of the embodiments, other than the film formation process exemplified in each of the embodiments. Further, it is possible to replace a part of a configuration in some embodiments with a configuration in other embodiments, and it is also possible to add a configuration in some embodiments to a configuration in other embodiments. In addition, it is possible to add another configuration to a part of a configuration in each of the above-described embodiments, cancel the part of the configuration, or replace the part of the configuration with another configuration.

In the above-described embodiments, four gas introduction portions 506 are installed in the nozzle 227 in the width direction of the nozzle. However, five or more gas introduction portions 506 may be installed in the width direction of the nozzle by increasing the number of vertical plates 504 installed at the gas guide 500, and the number of gas guides 500 may be increased or decreased, as desired. In any case, a gas may be supplied to at least two of the gas introduction portions 506. In addition, a gas may be also supplied to three or more gas introduction portions 506, as desired.

In the above-described embodiments, the gas guide 500 is arranged inside the nozzle 227, and the inside of the nozzle is divided into two spaces in the vertical direction with four gas introduction portions 506 installed side by side in each of upper and lower spaces. The inside of the nozzle 227 may be divided into upper and lower spaces as desired, but may not be divided into upper and lower spaces.

In the above-described embodiments, when the first gas and the second gas are supplied individually to the substrate S, the gases are not supplied to the gas introduction portion 506 on the central side in the width direction of the nozzle, but are supplied to the gas introduction portions 506 on both sides in the width direction of the nozzle. Alternatively, the gases may not be supplied to the gas introduction portions 506 on both sides in the width direction of the nozzle, but may be supplied to the gas introduction portion 506 on the central side in the width direction of the nozzle. In this case as well, finally, the first gas or the second gas of the same amount may be discharged at the same velocity along the surface of the substrate S from the downstream ends of the gas introduction portions 506 on both sides and the downstream ends of the gas introduction portions 506 on the central side.

In the gas guide 500 of the above-described embodiments, the fluid communication portions 518 are installed at width-direction ends of the horizontal plate 502. Therefore, for example, the gases flowing into two upper and lower gas introduction portions 506 installed on both sides in the width direction of the nozzle may be caused to enter each other via the fluid communication portions 518. For this reason, as an example, by supplying the first gas to one of the two upper and lower gas introduction portions 506 and supplying the second gas to the other of the two upper and lower gas introduction portions 506, the first gas and the second gas may be mixed in the nozzle 227, and the mixed gas may be discharged from the upper and lower gas introduction portions 506 toward the substrate S. Further, in this case, a structure of the gas supply structure 212 may be changed such that different types of gases are supplied to the upper gas introduction portion 506 and the lower gas introduction portion 506.

Further, when the same gas is supplied to the two upper and lower gas introduction portions 506 on both sides in the width direction of the nozzle, gases may not be mixed within the nozzle 227. Therefore, the fluid communication portion 518 at the width-direction end of the horizontal plate 502 may be omitted.

In the gas guide 500, as an example, diameters of the holes 514 formed at the walls 512 on the downstream side corresponding to the gas introduction portions 506 on both sides in the width direction of the nozzle may be set to be smaller than diameters of the holes 514 formed at the walls 512 on the downstream side corresponding to the two gas introduction portions 506 on the central side in the width direction of the nozzle.

As a result, a passage resistance when a gas passes through the holes 514 in the walls 512 corresponding to the gas introduction portions 506 on both sides in the width direction of the nozzle is greater than a passage resistance when a gas passes through the holes 514 in the walls 512 corresponding to the gas introduction portions 506 on the central side in the width direction of the nozzle, and internal pressures of the gas introduction portions 506 on both sides in the width direction of the nozzle are relatively higher than internal pressures of the gas introduction portions 506 on the central side in the width direction of the nozzle. This makes it possible to increase an amount of the gas that enters the gas introduction portions 506 on the central side in the width direction of the nozzle from the gas introduction portions 506 on both sides in the width direction of the nozzle via the fluid communication portion 520.

That is, by changing the diameters of the holes 514, it is possible to control the amount of the gas passing through the fluid communication portion 520 via which the gas is moved from one gas introduction portion 506 to the other gas introduction portion 506, which are adjacent to each other. Further, in the nozzle 227, by changing the width Wa of the fluid communication portion 520, it is also possible to control the amount of the gas passing through the fluid communication portion 520.

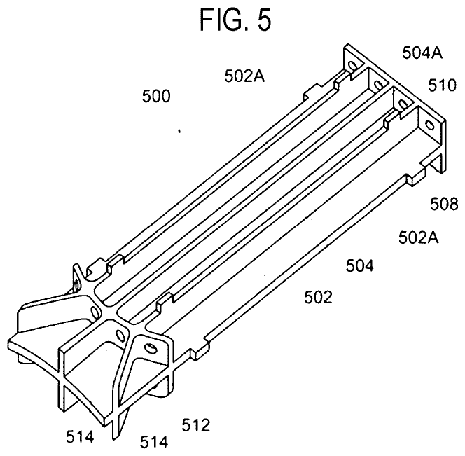

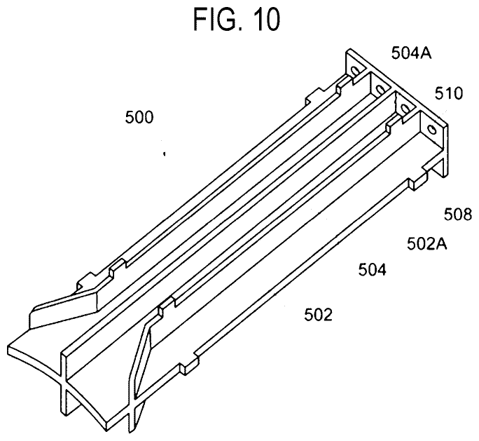

In the gas guide 500 described in the above-described embodiments, the walls 512 are installed at the downstream side. However, the walls 512 may be installed as desired, or the walls 512 may not be installed as shown in FIG. 10. The walls 508 on the upstream side may also be installed as desired, or may not be installed. In the gas guide 500 shown in FIG. 10, the same components as those in the gas guide 500 shown in FIG. 5 are designated by the same reference numerals, and descriptions thereof will be omitted.

Further, the fluid communication portions 518 and 520 may be installed at desired locations such that the flow of the processing gas becomes the wide flow which is symmetrical in the left-right direction with respect to the substrate S.

The nozzles 227 may be stacked one over another according to the number of substrates S to be processed. When processing one substrate S, one nozzle 227 may be installed. The present disclosure may also be applied to a case where one substrate S is processed, and the same effects as those of the above-described embodiments may be obtained.

Although the gas guide 500 described in the above-described embodiments is constituted by the plate, but may be constituted by a component other than the plate.

The term “substrate” used herein may refer to a substrate itself or a stacked body of a substrate and a predetermined layer or film formed on a surface of the substrate. The phrase “a surface of a substrate” used herein may refer to a surface of a substrate itself or a surface of a predetermined layer or the like formed on a substrate. The expression “a predetermined layer is formed on a substrate” used herein may mean that a predetermined layer is directly formed on a surface of a substrate itself or that a predetermined layer is formed on a layer or the like formed on a substrate. The term “substrate” used herein may be synonymous with the term “wafer.”

Although not specifically described in the above-described embodiments, each element is not limited to one, and may be present in multiple numbers, unless otherwise specified in the present disclosure.

In the above-described embodiments, the example in which a film is formed by using the substrate processing apparatus configured to process a plurality of substrates is described. The present disclosure is not limited to the above-described embodiments, and may be suitably applied, for example, to a case where a film is formed by using a substrate processing apparatus configured to process a single substrate. Further, the present disclosure may be also suitably applied to a substrate processing apparatus including a cold-wall-type process furnace or a substrate processing apparatus including a hot-wall-type process furnace, and may be also applied to a substrate processing apparatus including a nozzle configured to blow out a processing gas along a substrate.

When using these substrate processing apparatuses, each process may be performed with the same process procedures and process conditions as those of the above-described embodiments and modifications, and the same effects as those of the above-described embodiments and modifications may be obtained. The above-described embodiments and modifications may be used in appropriate combination. Process procedures and process conditions in such a case may be, for example, the same as those of the above-described embodiments and modifications.

According to the present disclosure in some embodiments, it is possible to uniformly process a surface of a substrate.

While certain embodiments are described above, these embodiments are presented by way of example, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a process chamber in which at least one substrate is processed;
at least one nozzle including a plurality of gas introduction passages configured to introduce a gas and a fluid communication portion configured to partially bring the plurality of gas introduction passages into fluid communication with each other; and
a plurality of gas suppliers configured to supply the gas to the plurality of gas introduction passages.

2. The substrate processing apparatus of claim 1, wherein the plurality of gas introduction passages are formed by a gas guide arranged inside the at least one nozzle, and
wherein the fluid communication portion is installed between an inner wall of the at least one nozzle and an outer edge of the gas guide.

3. The substrate processing apparatus of claim 1, wherein the gas is supplied from the plurality of gas suppliers to at least two gas introduction passages of the plurality of gas introduction passages.

4. The substrate processing apparatus of claim 3, wherein the gas includes a processing gas, and
wherein an inert gas is supplied from the plurality of gas suppliers to a gas introduction passage other than a gas introduction passage to which the processing gas is supplied among the plurality of gas introduction passages.

5. The substrate processing apparatus of claim 4, wherein a flow rate of the inert gas supplied from the plurality of gas suppliers is 10% or less of a flow rate of the processing gas.

6. The substrate processing apparatus of claim 2, wherein the gas guide is constituted by plates.

7. The substrate processing apparatus of claim 6, wherein the plates include a horizontal plate and vertical plates, and
wherein the horizontal plate and the vertical plates constitute the plurality of gas introduction passages inside the at least one nozzle.

8. The substrate processing apparatus of claim 7, wherein at least one protrusion that comes into contact with the inner wall of the at least one nozzle and constitutes the fluid communication portion is formed on a plate end surface of the horizontal plate or at least one of the vertical plates.

9. The substrate processing apparatus of claim 1, wherein the at least one substrate includes a plurality of substrates, and
wherein the process chamber includes a substrate holder configured to be capable of holding the plurality of substrates.

10. The substrate processing apparatus of claim 9, wherein the at least one nozzle includes a plurality of nozzles installed in multiple stages in a height direction of the substrate holder.

11. The substrate processing apparatus of claim 1, wherein the fluid communication portion is configured such that two types of processing gases introduced into the plurality of gas introduction passages are capable of being mixed inside the at least one nozzle.

12. The substrate processing apparatus of claim 11, wherein when the two types of processing gases are mixed, the two types of processing gases are respectively supplied to two adjacent gas introduction passages among the plurality of gas introduction passages.

13. The substrate processing apparatus of claim 12, wherein an inert gas is supplied to a gas introduction passage, which is not one of the two adjacent gas introduction passages but is one of the plurality of gas introduction passages.

14. The substrate processing apparatus of claim 13, wherein a flow rate of the inert gas supplied from the plurality of gas suppliers is 50% or less of a flow rate of a mixed gas obtained by mixing the two types of processing gases.

15. The substrate processing apparatus of claim 1, wherein the gas is supplied parallel to a surface of the at least one substrate.

16. The substrate processing apparatus of claim 7, wherein the vertical plates on both sides in a width direction of the at least one nozzle are widened outward in the width direction from an upstream side to a downstream side of a flow of a processing gas.

17. A nozzle configured to introduce a processing gas into a process chamber in which a substrate is processed, comprising:
a plurality of gas introduction passages configured to introduce a gas; and
a fluid communication portion configured to partially bring the plurality of gas introduction passages into fluid communication with each other.

18. A method of processing a substrate, comprising:
loading the substrate into a process chamber; and
supplying a gas into the process chamber from a nozzle including a plurality of gas introduction passages and a fluid communication portion configured to partially bring the plurality of gas introduction passages into fluid communication with each other.

19. A method of manufacturing a semiconductor device comprising the method of claim 18.

20. A non-transitory computer-readable recording medium storing a program that causes, by a computer, a substrate processing apparatus to perform a process including the method of claim 18.
